(19) United States
(12) Patent Application Publication
(10) Pub. No.: US 2015/0191124 A1
(43) Pub. Date: Jul. 9, 2015

(54) MOUNTING SYSTEM FOR ATTACHING MOBILE DEVICE

(71) Applicant: O2Micro Inc., Santa Clara, CA (US)

(72) Inventor: Sterling Du, Palo Alto, CA (US)

(73) Assignee: O2Micro Inc., Santa Clara, CA (US)

(21) Appl. No.: 14/146,859

(22) Filed: Jan. 3, 2014

(51) Int. Cl. B60R 7/04; H05K 5/02; F16B 11/00; F16M 13/02; F16B 47/00

(52) U.S. Cl. CPC B60R 7/04; F16M 13/022; F16B 47/00; F16B 11/006; H05K 5/0204; H05K 5/0247

(57) ABSTRACT

A mounting system for mounting a device, e.g., a mobile device, is disclosed. The mounting system includes a housing component and a securing component. The housing component is configured to secure a device. The securing component is coupled to the housing component and is configured to secure the mounting system to a surface. The securing component comprises a lower mounting component configured to secure the housing component to the surface from a bottom side of the housing component. The lower mounting component comprises a first connecting portion and a first attachment device configured to attach to the surface. The first connecting portion is configured to connect the lower mounting component to the bottom side of the housing component.

### FIELD OF THE PRESENT DISCLOSURE

The present disclosure relates generally to mechanisms for securing a device, for example a mobile device, and more specifically, to a mounting system.

### BACKGROUND

With the development of mobile devices such as mobile phones and the increment of the screen size of mobile devices, people tend to use these mobile devices to achieve different functions, such as navigating. Moreover, a mobile device may even act as display panel of a vehicle, e.g., a motorcycle. The mobile device can show digital maps and display driving information such as speed, mileage and battery capacity after establishing communication with the vehicle. With the powerful functions of current mobile device, the mobile device can provide more information than the traditional display panel embedded in the vehicle.

However, unlike cars which have similar structural designs, different motorcycles may differ a lot in the structural design of their front portion. It is difficult to find a common place on a motorcycle for a mounting system to attach. For this reason, a conventional mounting system is usually customized for attaching to a particular motorcycle and cannot be used for another type of motorcycle.

Therefore, there exists a need to provide a more flexible mounting system for attaching, e.g., a mobile device to a vehicle that can adapt to different surfaces of vehicles and be convenient for mounting and dismounting the mobile device.

### SUMMARY

Embodiments described herein relate to mounting system for mounting a device.

In an embodiment, a mounting system for mounting a device is disclosed. The mounting system includes a housing component and a securing component. The housing component is configured to secure the device. The securing component is coupled to the device housing component and is configured to secure the mounting system to a surface. The securing component comprises a lower mounting component configured to secure the housing component to the surface from bottom side of the housing component. The lower mounting component comprises a first connecting portion and a first attachment device. The first connecting portion is configured to connect the lower mounting component to a bottom of the mobile device housing component. The first attachment is configured to attach to the surface.

In another embodiment, a mounting system for mounting a device is disclosed. The mounting system includes a housing component and a securing component. The housing component is configured to secure the device. The securing component is coupled to the housing component and is configured to secure the mounting system to a surface. The securing component comprises a first mounting component and a second mounting component. The first mounting component is placed at a bottom of the device housing component and is configured to secure the housing component to the surface from bottom side. The second mounting component is placed at a top of the device housing component and is configured to secure the housing component to the surface from top side.

Additional benefits and novel features will be set forth in part in the description which follows, and in part will become apparent to those skilled in the art upon examination of the following and the accompanying drawings or may be learned by production or operation of the disclosed embodiments. The benefits of the present embodiments may be realized and attained by practice or use of various aspects of the methodologies, instrumentations and combinations set forth in the detailed description set forth below.

### BRIEF DESCRIPTION OF THE DRAWINGS

Features and benefits of embodiments of the claimed subject matter will become apparent as the following detailed description proceeds, and upon reference to the drawings, wherein like numerals depict like parts. These exemplary embodiments are described in detail with reference to the drawings. These embodiments are non-limiting exemplary embodiments.

FIG. 1A illustrates a lateral view of a mounting system, in accordance with an embodiment of the present disclosure;

FIG. 1B illustrates a lateral view of the mounting system in FIG. 1A with a mobile device mounted, in accordance with an embodiment of the present disclosure;

FIG. 1C illustrates a front view of a mounting system, in accordance with an embodiment of the present disclosure;

FIG. 1D illustrates a front view of a mounting system with a mobile device mounted, in accordance with an embodiment of the present disclosure;

FIG. 1E illustrates a lateral view of the mobile device housing component in FIG. 1A with a cover, in accordance with an embodiment of the present disclosure;

FIG. 1F illustrates a front view of the mobile device housing component in FIG. 1A with a cover, in accordance with an embodiment of the present disclosure;

FIG. 2A illustrates a lateral view of a mounting system, in accordance with another embodiment of the present disclosure;

FIG. 2B illustrates a front view of a mounting system, in accordance with another embodiment of the present disclosure;

FIG. 2C illustrates a front view of a mounting system with a mobile device mounted, in accordance with another embodiment of the present disclosure;

FIG. 2D illustrates a front view of a mounting system with a cover attached, in accordance with another embodiment of the present disclosure;

FIG. 2E illustrates a back view of a mounting system with a cover attached, in accordance with another embodiment of the present disclosure;

FIG. 2F illustrates a lateral view of a mounting system, in accordance with another embodiment of the present disclosure;

FIG. 2G illustrates a front view of a mounting system, in accordance with another embodiment of the present disclosure;

FIG. 3A illustrates a front view of a mounting system, in accordance with another embodiment of the present disclosure;

FIG. 3B illustrates a front view of a mounting system, in accordance with another embodiment of the present disclosure;

FIG. 4A illustrates a lateral view of a mounting system, in accordance with another embodiment of the present disclosure;

FIG. 4B illustrates a front view of a mounting system, in accordance with another embodiment of the present disclosure;

FIG. 4C illustrates a front view of a mounting system with a mobile phone mounted, in accordance with another embodiment of the present disclosure;

FIG. 5A illustrates a lateral view of a mounting system, in accordance with another embodiment of the present disclosure;

FIG. 5B illustrates a front view of a mounting system, in accordance with another embodiment of the present disclosure;

FIG. 5C illustrates a front view of a mounting system with a mobile phone mounted, in accordance with another embodiment of the present disclosure;

FIG. 6A illustrates a front view of a mounting system, in accordance with another embodiment of the present disclosure;

FIG. 6B illustrates a back view of a mounting system, in accordance with another embodiment of the present disclosure;

FIG. 7 illustrates a front view of a mounting system, in accordance with another embodiment of the present disclosure;

FIG. 8 illustrates a front view of a mounting system attached to a motorcycle with a mobile device mounted, in accordance with an embodiment of the present disclosure;

FIG. 9 illustrates a mounting system with an electric wire and attached to a motorcycle, in accordance with an embodiment of the present disclosure;

FIG. 10A illustrates a mounting system, in accordance with another embodiment of the present disclosure;

FIG. 10B illustrates a lateral view of a mounting system in FIG. 10A, in accordance with another embodiment of the present disclosure;

FIG. 11A illustrates a mounting system, in accordance with another embodiment of the present disclosure; and

FIG. 11B illustrates a lateral view of a mounting system in FIG. 11A, in accordance with another embodiment of the present disclosure.

### DETAILED DESCRIPTION

Reference will now be made in detail to the embodiments of the present disclosure. While the present disclosure will be described in conjunction with these embodiments, it will be understood that they are not intended to limit the present disclosure to these embodiments. On the contrary, the present disclosure is intended to cover alternatives, modifications and equivalents, which may be included within the spirit and scope of the present disclosure as defined by the appended claims.

Furthermore, in the following detailed description of the present disclosure, numerous specific details are set forth in order to provide a thorough understanding of the present disclosure. However, it will be recognized by one of ordinary skill in the art that the present disclosure may be practiced without these specific details. In other instances, well known methods, procedures, components, and circuit have not been described in detail as not to unnecessarily obscure aspects of the present disclosure.

The present disclosure provides a mounting system for mounting devices such as a mobile device (e.g., a mobile phone, a tablet computer, etc.), a GPS console, a video or still camera, and the like. The mounting system can be attached to any suitable place of a vehicle, e.g., a flat surface or a slightly cambered surface at the front portion of the vehicle. In an embodiment, after mounted to the mounting system, a mobile device can be used as a dashboard or display panel of the vehicle.

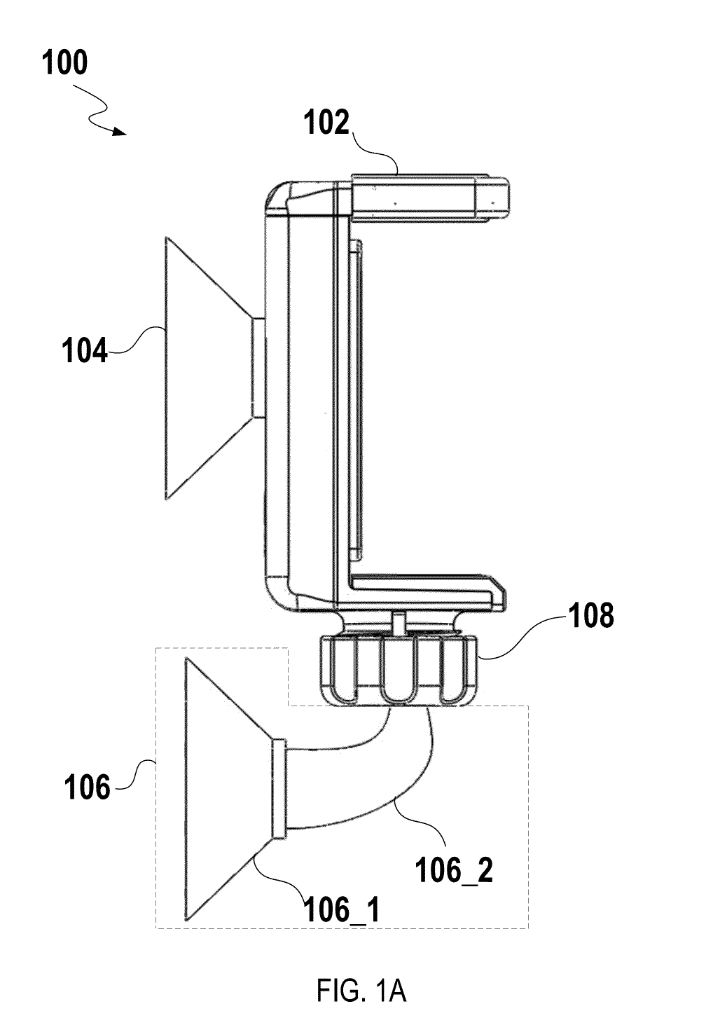

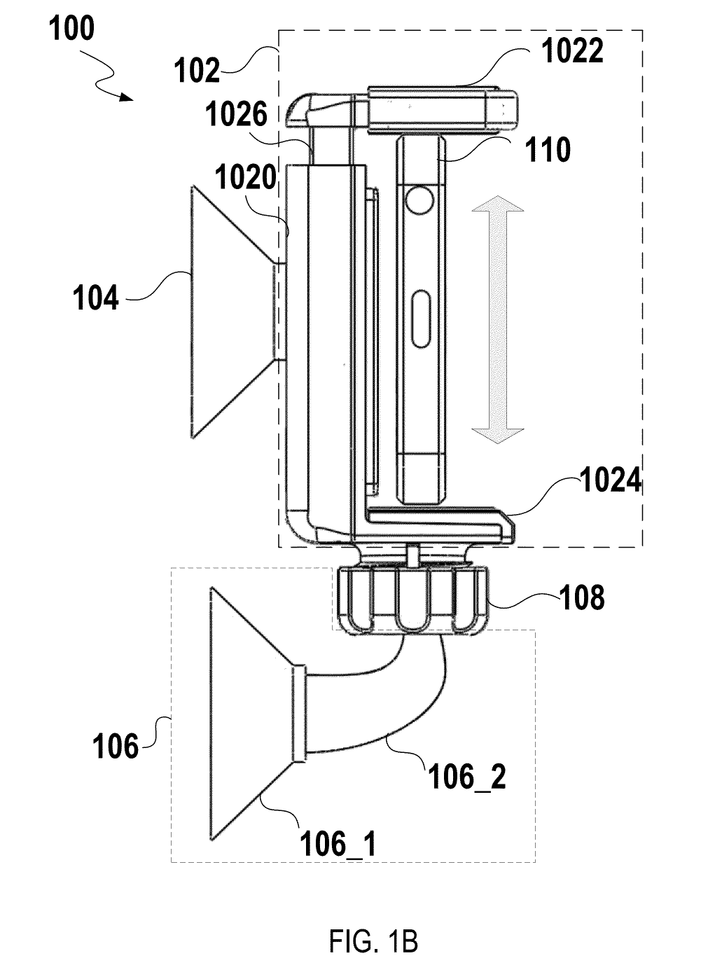

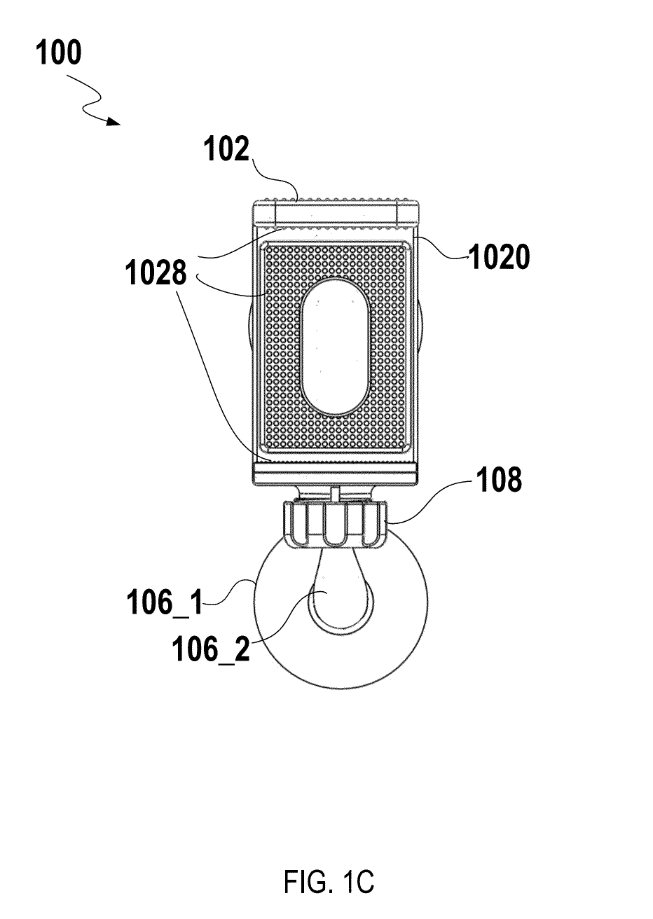

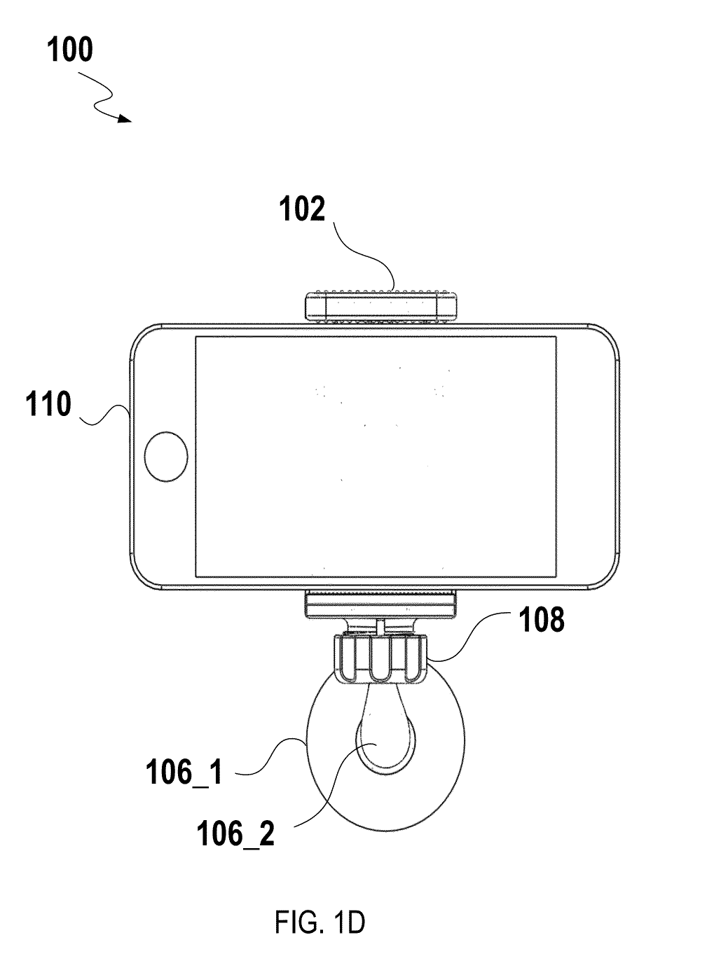

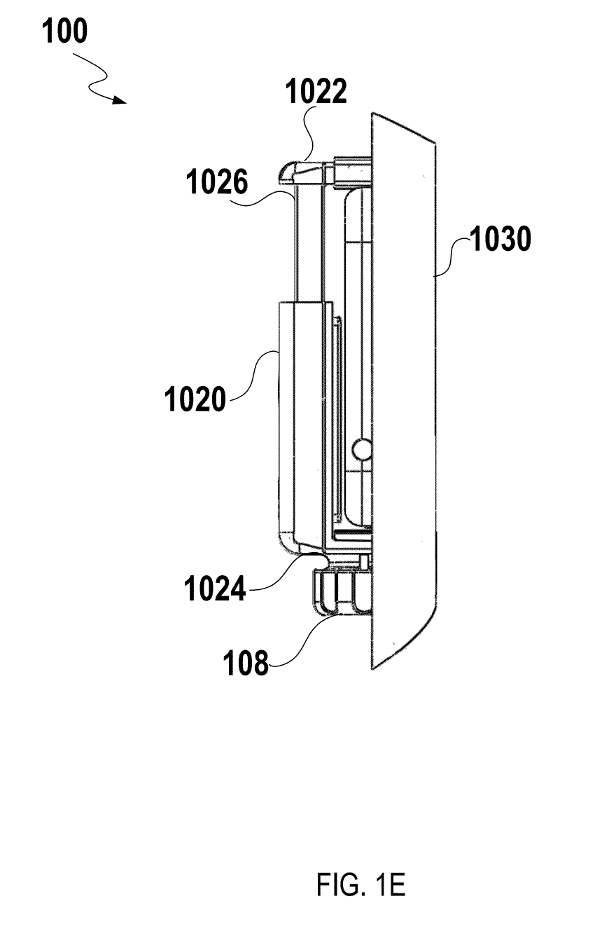

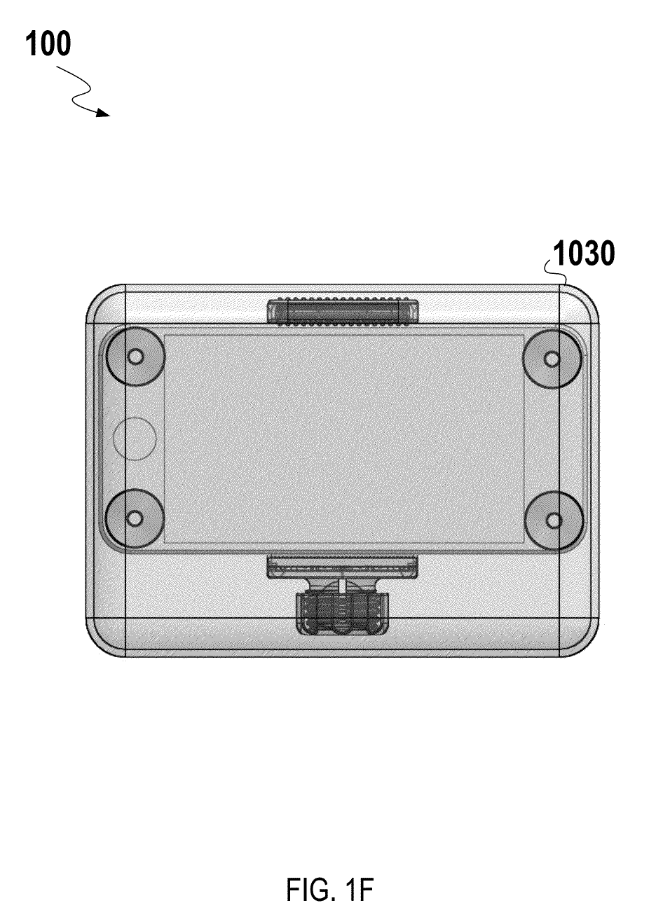

FIGS. 1A-1F illustrates embodiments of a mounting system 100 which can attach to a vehicle and can hold a mobile device. FIG. 1A illustrates a lateral view of a mounting system 100, in accordance with an embodiment of the present disclosure. As shown in FIG. 1A, the mounting system 100 includes a housing component 102 (for housing, e.g., a mobile device) and securing component. Housing component 102 is configured to secure a mobile device (not shown in FIG. 1A). A securing component is configured to secure the mounting system 100 to a surface of the vehicle. In the example of FIG. 1A, the securing component includes an upper mounting component (e.g., attachment device 104) and a lower mounting component (e.g., attachment device 106 and connecting portion 108). In an embodiment, attachment devices 104 and 106 can be, for example, suction cups that are configured to attach to the surface through suction or vacuum. In another embodiment, the attachment devices 104 and 106 may be adhesive tapes, flexible permanent magnets, magnetic latches, fasteners, screws, bolts, rivets, and the like. In other embodiments, the attachment devices 104 and 106 may be any other suitable devices that can be configured to attach to a flat or slightly chamfered surface.

The upper mounting component is placed at the back of housing component 102 and is configured to secure housing component 102 to the surface from back side of housing component 102. The lower mounting component is placed at the bottom of housing component 102 and is configured to secure housing component 102 to the surface from bottom side of housing component 102. In the example of FIG. 1A, attachment device 104 is placed at the back plate of housing component 102. Attachment device 106 is connected to housing component 102 through connecting portion 108. Attachment device 104 and attachment device 106 can be attached to any surface of the vehicle. In an embodiment, attachment device 106 may have a ball-end at the end opposite the attaching surface. In an embodiment as shown in FIG. 1A, attachment device 106 may include a suction cup 106_1 and a supporting bracket 106_2. One end of supporting bracket 106_2 is a ball-end. The other end of supporting bracket 106_2 may be flat and is attached with suction cup 106_1. As shown in FIG. 1A, supporting bracket 106_2 may bend and form an angle of, e.g., 90 degrees. In other embodiment, supporting bracket 106_2 may be straight or bend with another angle according to practical needs (e.g., an angle of 45 degrees). One skilled in the art will be able to suitably modify the angle at which supporting bracket 106_2 bends as needed for a desired embodiment. The skilled artisan will also recognize that the ball-end of supporting bracket 106_2 may be a male or a female ball-end.

Connecting portion 108 is attached to the bottom side of housing component 102 for connecting attachment device 106 to housing component 102. In an embodiment, connecting portion 108 may be, e.g., a ball joint socket which can mate with the ball-end of attachment device 106. The ball-end of attachment device 106 can rotate in the ball joint socket. Thus connecting portion 108 enables attachment device 106 to have 360-degree adjustment. Alternatively, connecting portion 108 may be other mechanism (e.g., a screw, pin, rod, or other suitable device).

FIG. 1B-1D provides various alternative views of mounting system 100 of the present disclosure. FIG. 1B illustrates a lateral view of mounting system 100 in FIG. 1A with a mobile device 110 mounted, in accordance with an embodiment of the present disclosure. As shown in FIG. 1B, housing component 102 has a back portion 1020, a top portion 1022 and a bottom portion 1024. Back portion 1020, top portion 1022 and bottom portion 1024 comprise a space to clamp the mobile device. The shape of back portion 102, top portion 1022, and bottom portion 1024 may be, but not limited to, rectangle, square, polygon or other shapes. While back portion 102 and top portion 1022, and back portion 102 and bottom portion 1024 as shown herein to form right angles, it will be obvious to one skilled in the art that other angles are also possible, Moreover, while back portion 102, top portion 1022 and bottom portion 1024 are all shown to have flat surfaces, it is possible to modify them to have curved surfaces, e.g., to form an arc that can hold, e.g., a cylindrical object or a shaft.

Distance between top portion 1022 and bottom portion 1024 can be adjusted. Back portion 1020 includes an extendable plate 1026 which has one end connected with top portion 1020 to enable top portion 1020 move vertically relative to bottom portion 1024 so that the total length of back portion 1020 can be adjusted to accommodate mobile devices with different sizes. Any suitable mechanism may be used for extending extendable plate 1026. For example, in an embodiment, extendable plate 1026 may be provided with a sliding gear assembly such that extendable plate 1026 moves upwards when a rotor is rotated. In another embodiment, extendable plate 1026 may be provided with a spring mechanism to load extendable plate 1026 it can be extended upwards by application of force and it snaps back when the force is removed. Advantageously, housing component 102 can accommodate various mobile devices of different sizes.

FIG. 1C illustrates a front view of mounting system 100, in accordance with an embodiment of the present disclosure. As shown in FIG. 1C, the front surface of back portion 1020, the lower surface of top portion 1022, the upper surface of bottom portion 1024 are installed with transitional cushions 1028 to ease the impact to the mobile device and to add the friction in order to clamp the mobile device more tightly. For example, the material of cushion 1028 may be, but not limited to sponge, foam, silicone rubber, or other soft materials. FIG. 1D illustrates a front view of mounting system 100 with a mobile device (e.g., mobile phone 110) mounted, in accordance with an embodiment of the present disclosure. As shown in FIG. 1D, by using mounting system 100 of the present disclosure, mobile phone 110 may be placed horizontally.

In addition, mobile device housing component 102 may further include a cover 1030 that covers the mobile device. FIG. 1E illustrates a lateral view of housing component 102 with cover 1030, in accordance with an embodiment of the present disclosure. FIG. 1F illustrates a front view of housing component 102 with cover 1030, in accordance with an embodiment of the present disclosure. In one embodiment, cover 1030 can act as a protective case for waterproofing and for protecting the mobile device from damage. Cover 1030, back portion 1020, top portion 1022 and bottom portion 1024 form an enclosed space to hold the mobile device. In an embodiment shown in FIG. 1F, cover 1030 may be closed with aid of four attachment devices, e.g., suction cups, placed at an inner surface of cover 1030. In an embodiment, the attachment devices can be placed at a location on the inner surface of cover 1030 where they are matched to the four corners of the display screen of the mobile device after closing the cover. Cover 1030 may have a relatively high transparency so that the user can still clearly see the information displayed on the screen of the mobile device through cover 1030. Cover 1030 may be made from a transparent, waterproof material such as, for example, acrylic, or other suitable hard polymers.

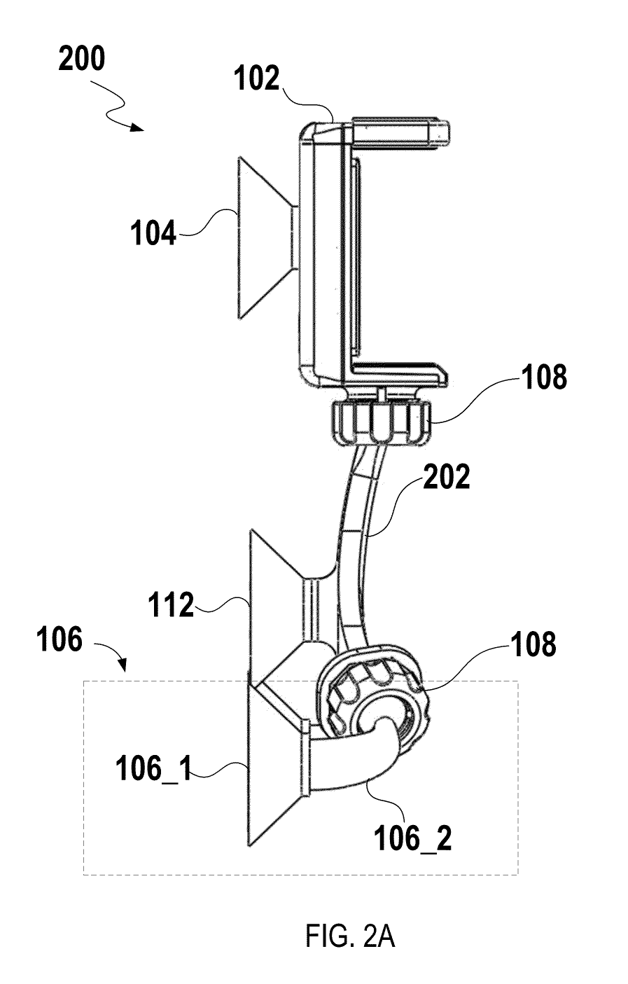

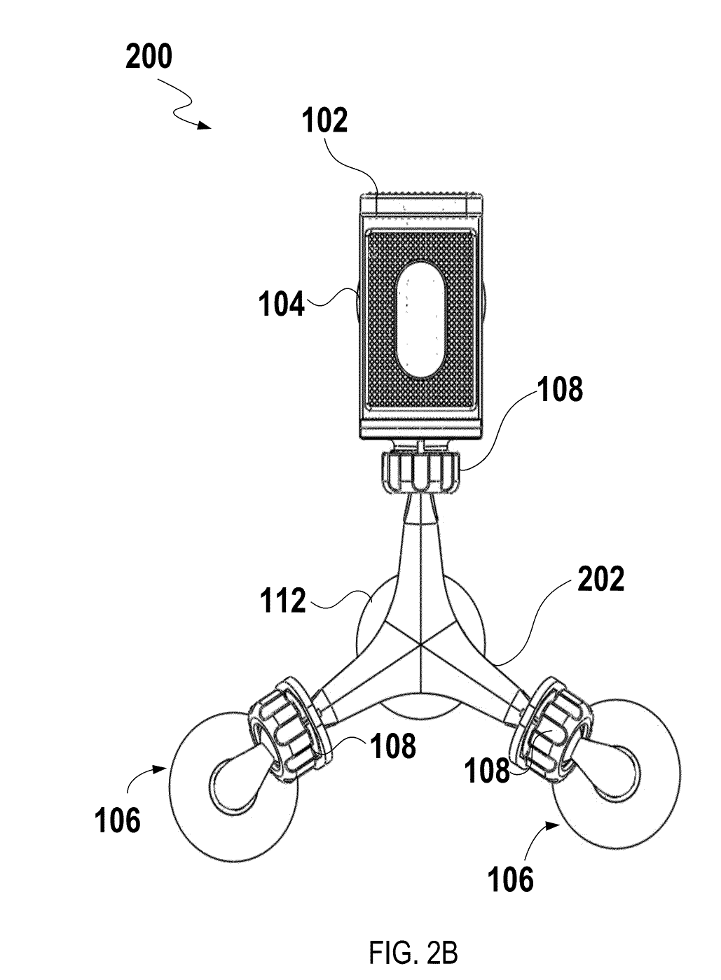

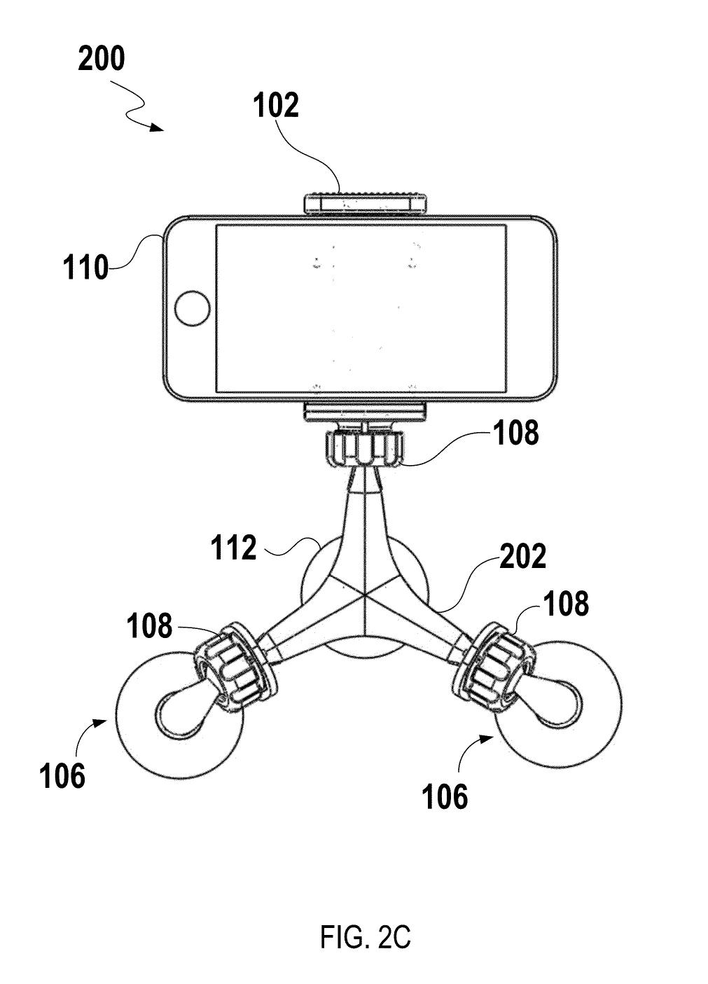

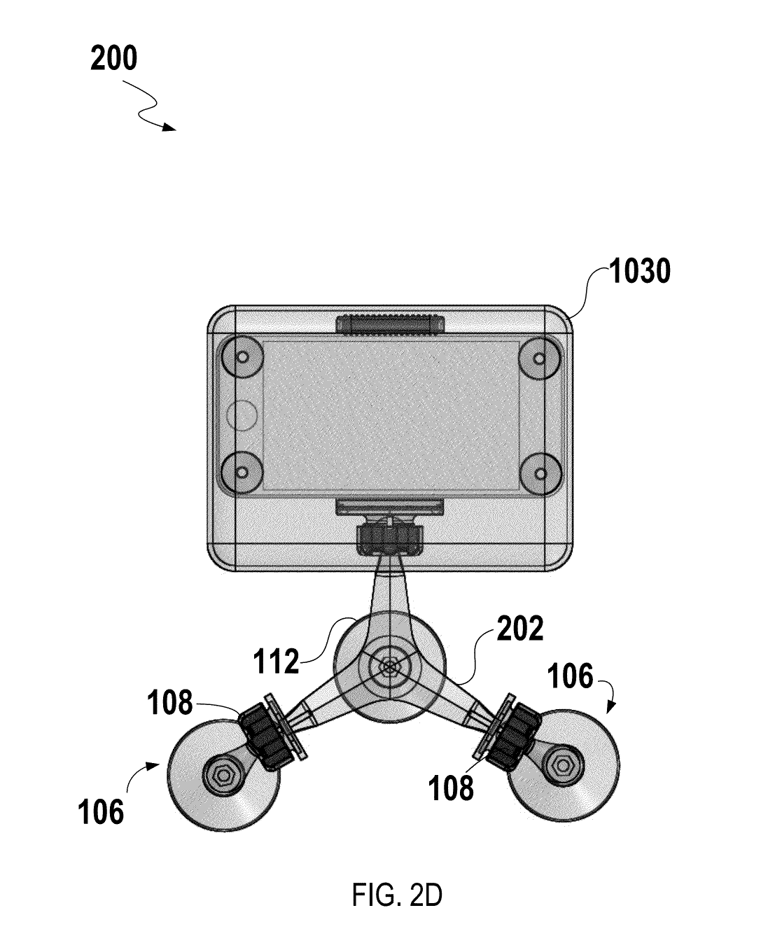

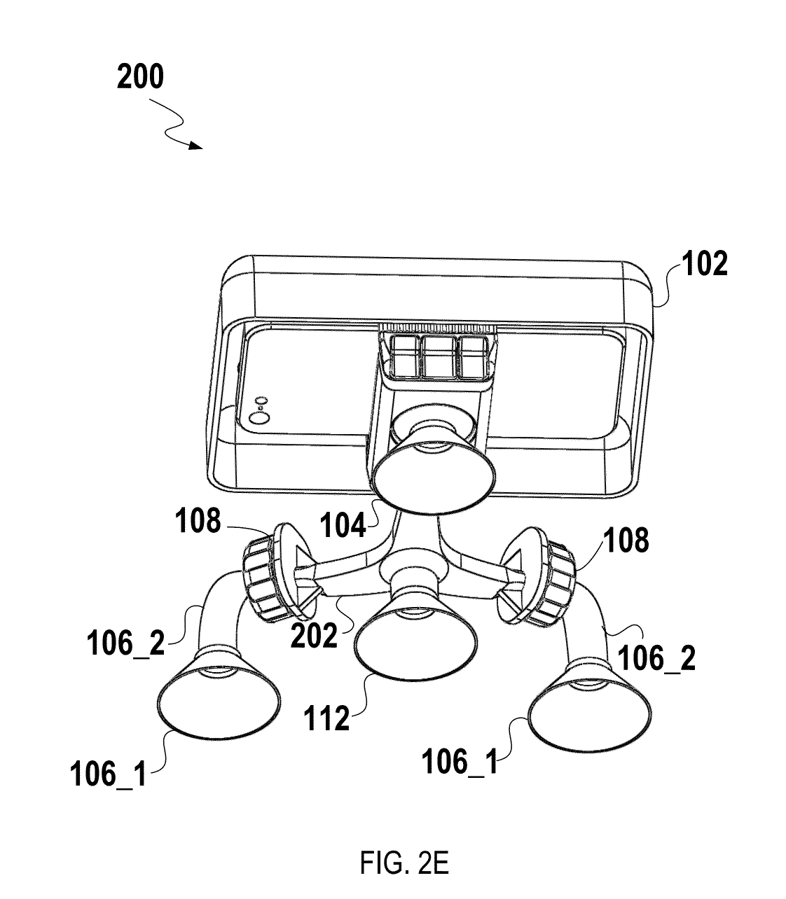

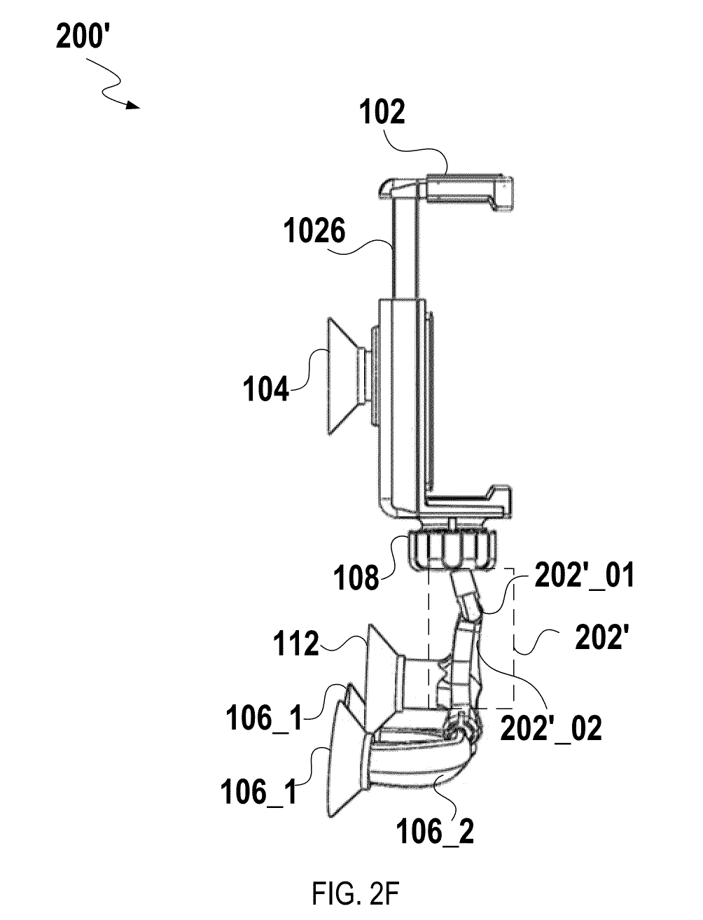

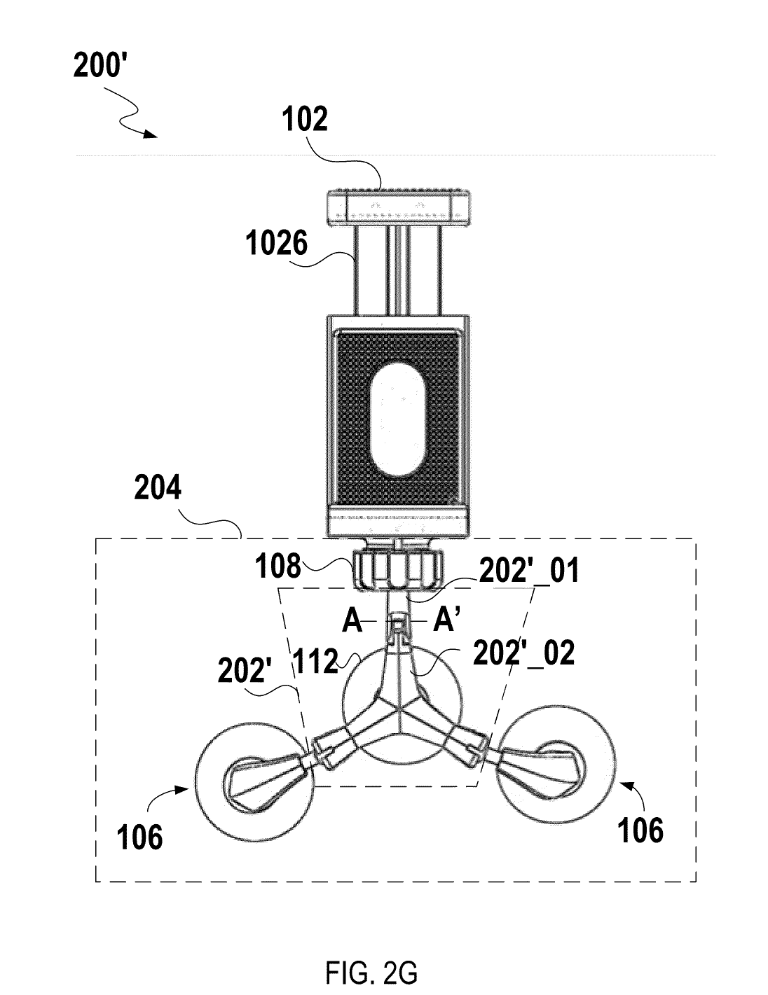

FIGS. 2A-2E illustrates another embodiment of a mounting system 200 which can mount a mobile device and can attach to a vehicle. FIG. 2A illustrates a lateral view of a mounting system 200, in accordance with another embodiment of the present disclosure. FIG. 2B illustrates a front view of mounting system 200, in accordance with another embodiment of the present disclosure. Elements labeled the same as in FIGS. 1A-1F have similar functions. Comparing with mounting system 100, mounting system 200 has a different securing component. The securing component of mounting system 200 includes an upper mounting component (e.g., a suction cup 104) and a lower mounting component. In the example of FIG. 2A-2E, the lower mounting component includes a supporting bracket 202, two attachment devices 106, a third attachment device 112 and three connecting portions 108.

Supporting bracket 202 may include three branches joined at a vertex. The branches may be symmetrically disposed about the vertex. For example, in an embodiment, the angle between two neighboring branches may be 120 degree. One branch of supporting bracket 202 may have a ball-end and may be connected to housing component 102 through a connecting portion 108. In one embodiment, the branch may secure to housing component 102 in similar ways as attachment device 106 described in FIG. 1A does. The other two branches of the supporting bracket 202 may each be connected with attachment device 106. In one embodiment, the connection between the branches and attachment devices 106 may use the same connecting mechanism as the connection between attachment device 106 and housing component 102 in FIG. 1A does. Two connecting portions 108 are attached at the end of the two branches to connect the branches with attachment devices 106, respectively. Similarly, connecting portions 108 enable attachment devices 106 to have 360-degree adjustment. In addition, third attachment device 112 is attached at a back surface of the vertex where the three branches of supporting bracket 202 connect to secure housing component 102 from back side.

FIG. 2C illustrates a front view of mounting system 200 with a mobile device (e.g., mobile phone 110) mounted, in accordance with another embodiment of the present disclosure. FIG. 2D illustrates a front view of a mounting system 200 with a cover 1030 attached, in accordance with another embodiment of the present disclosure. FIG. 2E illustrates a back view of mounting system 200 with cover 1030 attached, in accordance with another embodiment of the present disclosure.

Advantageously, with more attachment devices attached and with the flexible adjustment of the angles of attachment devices enabled by the connecting portions 108, mounting system 200 can be attached on complex shaped surface.

FIG. 2F illustrates a lateral view of mounting system 200′, in accordance with another embodiment of the present disclosure. FIG. 2G illustrates a front view of mounting system 200′, in accordance with another embodiment of the present disclosure. Comparing with mounting system 200 in FIGS. 2A-2E, a first branch of supporting bracket 202′, which is connected to a bottom of the housing component 102, can be folded. Advantageously, the position of housing component 102 can be adjusted with even greater flexibility. In one embodiment, as shown in FIGS. 2F and 2G, the first branch may include two portions. One portion 202′_01 can rotate around an axis AA′ which crosses through the other portion 202′_02 to achieve the folding of the first branch. While in other embodiments, the folding of the branches can be achieved by other mechanisms. Moreover, the branches can be made from elastic materials and therefore can be bended and folded. In addition, in other embodiments, all of the branches of supporting bracket 202′ can be folded.

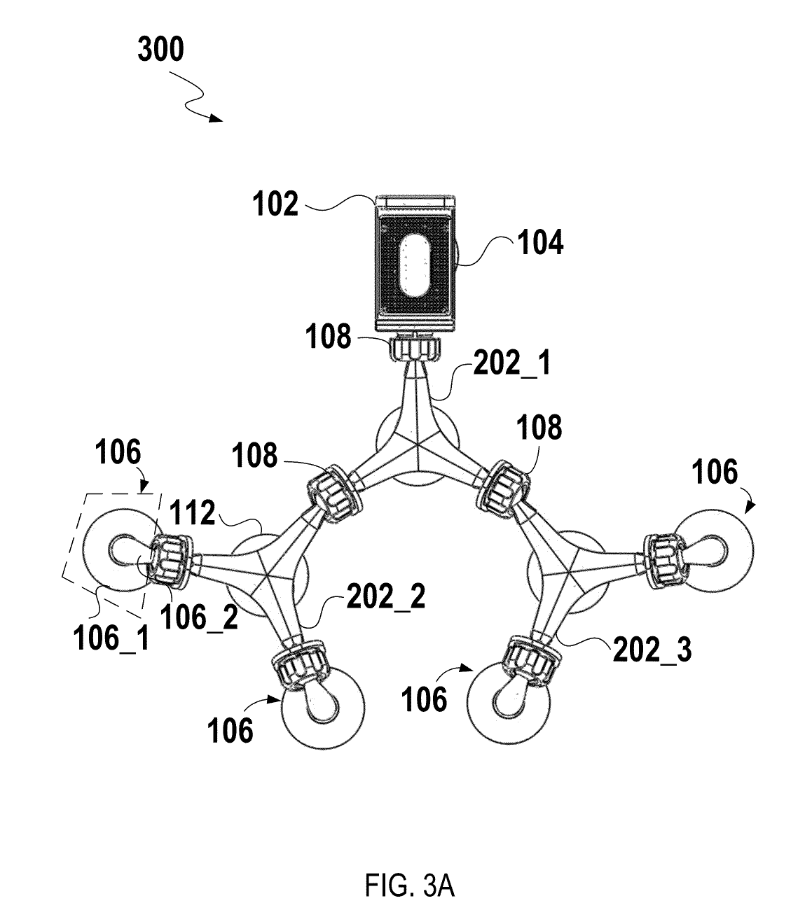

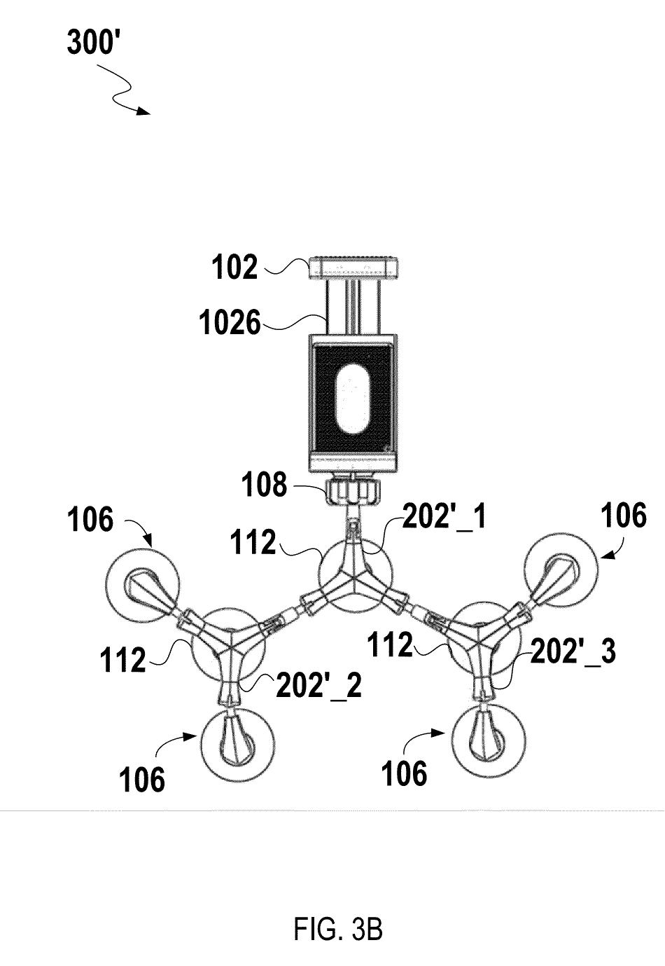

FIG. 3A illustrates another embodiment of a mounting system 300 which can mount a mobile device and can attach to a vehicle. Elements labeled as the same in FIGS. 2A-2E have similar functions. The securing component of mounting system 300 includes an upper mounting component (e.g., a suction cup 104) placed at the back of housing component 102 and configured to secure housing component 102 to a surface from a back side of housing component 102 and a lower mounting component placed at the bottom of housing component 102 and configured to secure housing component 102 to the surface from the bottom side. The lower mounting component of mounting system 300 includes multiple supporting brackets, multiple attachment devices and multiple connecting portions. The lower mounting component of mounting system 300 will be described in more details herein.

As shown in FIG. 3A, three supporting brackets are connected with each other by two connecting portions 108. More specifically, for a supporting bracket 202_1 which has three branches, a first branch and a second branch of supporting bracket 202_1 are connected to other two supporting brackets 202_2 and 202_3 through two connecting portions 108. A third branch with a ball-end of supporting bracket 202_1 is connected to housing component 102 through a connecting portion 108. Each of supporting brackets 202_2 and supporting bracket 202_3 has a branch which has a ball-end and is connected to supporting bracket 202_1 and has another two branches connected with attachment devices 106. Advantageously, because the branch with a ball-end can rotate in the socket of the connecting portion, by connecting multiple supporting brackets together, not only the angles of attachment devices, but also the angles between branches of different supporting brackets can be adjusted according to different surfaces of a vehicle. Mounting system 300 is more flexible. In addition, with more attachment devices, the stability of mounting system 300 is increased as well. In addition, although only three supporting brackets are shown in FIG. 3A, the mounting system of the present disclosure also covers embodiments which include more connected supporting brackets.

FIG. 3B illustrates a front view of a mounting system 300′, in accordance with another embodiment of the present disclosure. Similar with the mounting system 200′ in FIG. 2F and FIG. 2G, each supporting bracket 202_1, 202_2 or 202_3 may have one or more foldable branches which can provide greater flexibility when adjusting the position of housing component 102.

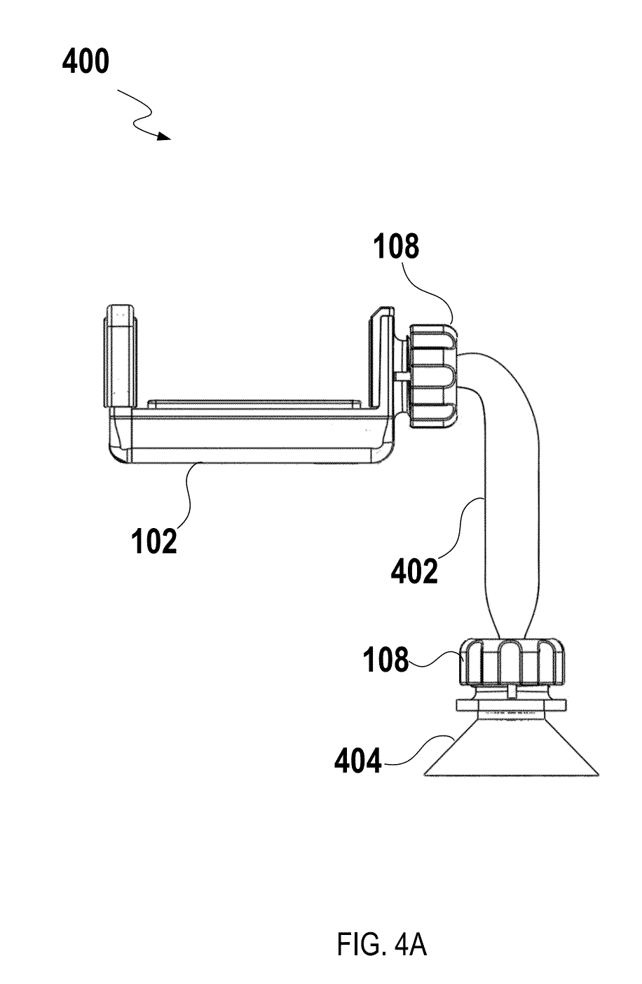

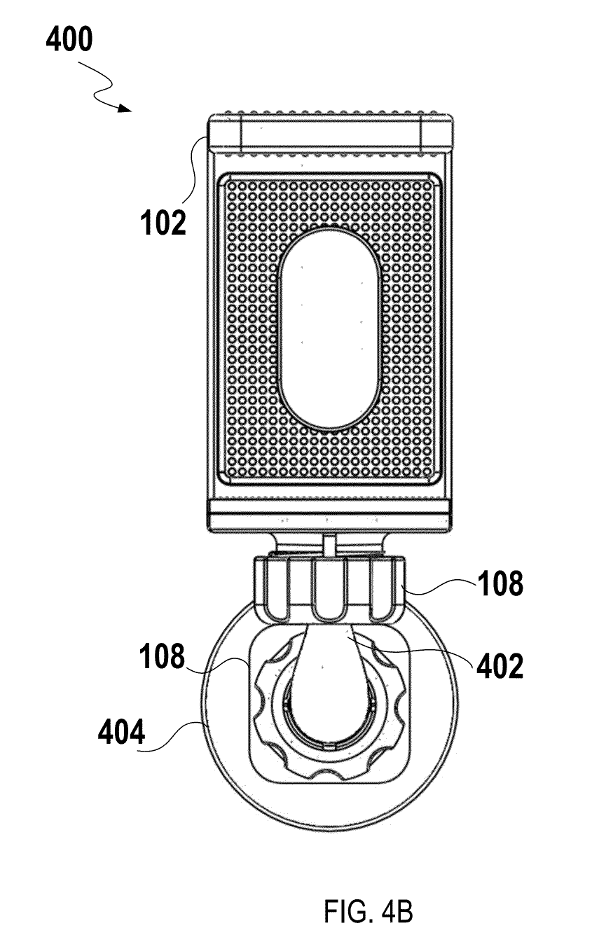

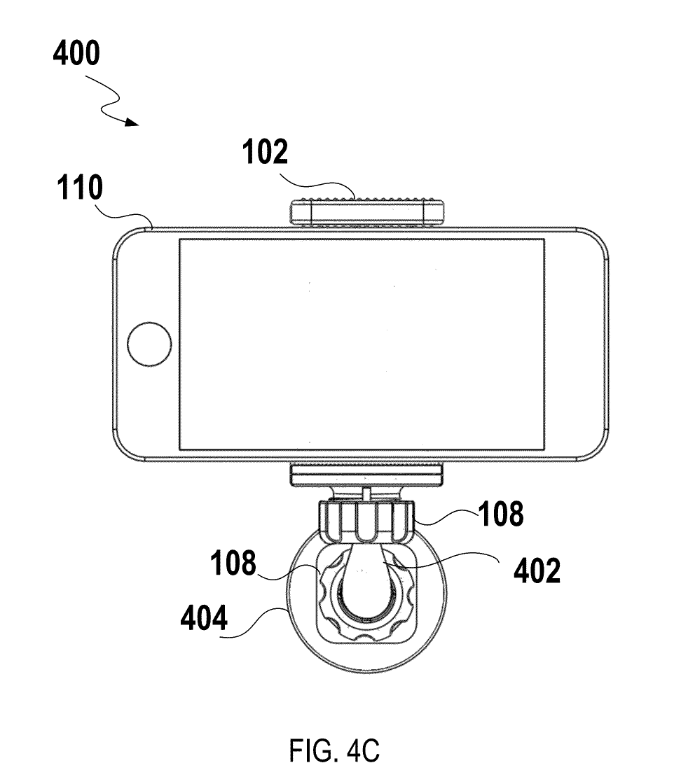

FIG. 4A-4C illustrates a mounting system 400 which can mount a mobile device and can attach to a vehicle, in accordance with an embodiment of the present disclosure. Elements labeled as the same in FIGS. 1A-1E have similar functions. FIG. 4A illustrates a lateral view of mounting system 400. As shown in FIG. 4A, an attachment device 404 is attached on the surface of a vehicle for securing mounting system 400. Housing component 102 is connected to attachment device 106 through a supporting bracket 402. Different from supporting bracket 202 in FIGS. 2A-2G, supporting bracket 402 only has one branch and both of two ends of the branch are ball-ends. More specifically, one end of the branch is connected to housing component 102 through a connecting portion 108. The other end of the supporting branch connects to attachment device 404 through another connecting portion 108. In one embodiment, similar to supporting bracket 202′, the branch of supporting bracket 402 may be foldable. The FIG. 4B illustrates a front view of mounting system 400. FIG. 4C illustrates a front view of mounting system 400 with a mobile device (e.g., a mobile phone 110) attached. Advantageously, with supporting bracket 402, mounting system 400 can hold up mobile phone 110 and users can adjust the position of housing component 102 according to their preference.

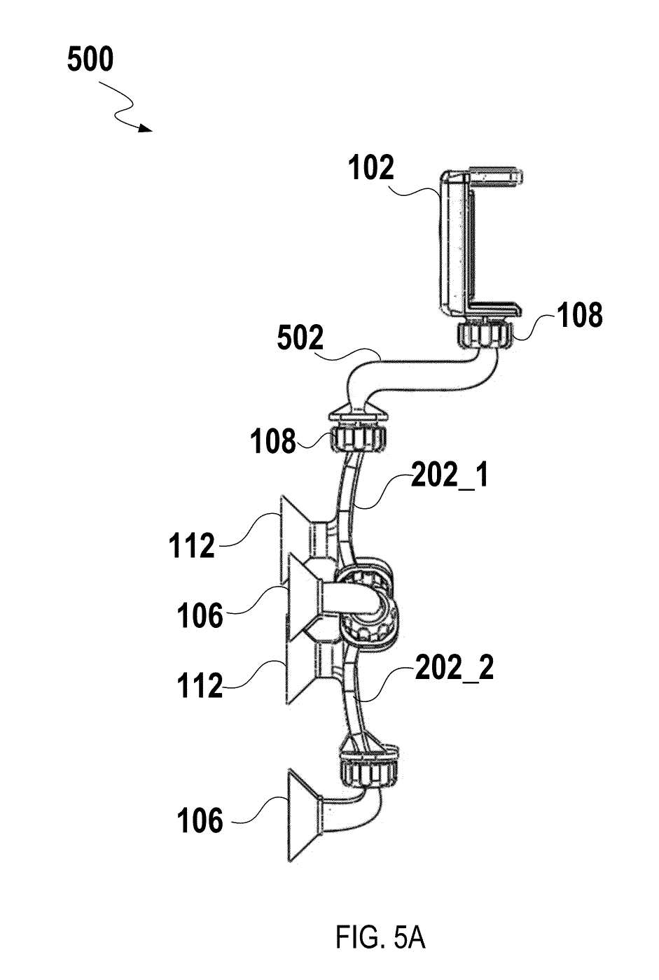

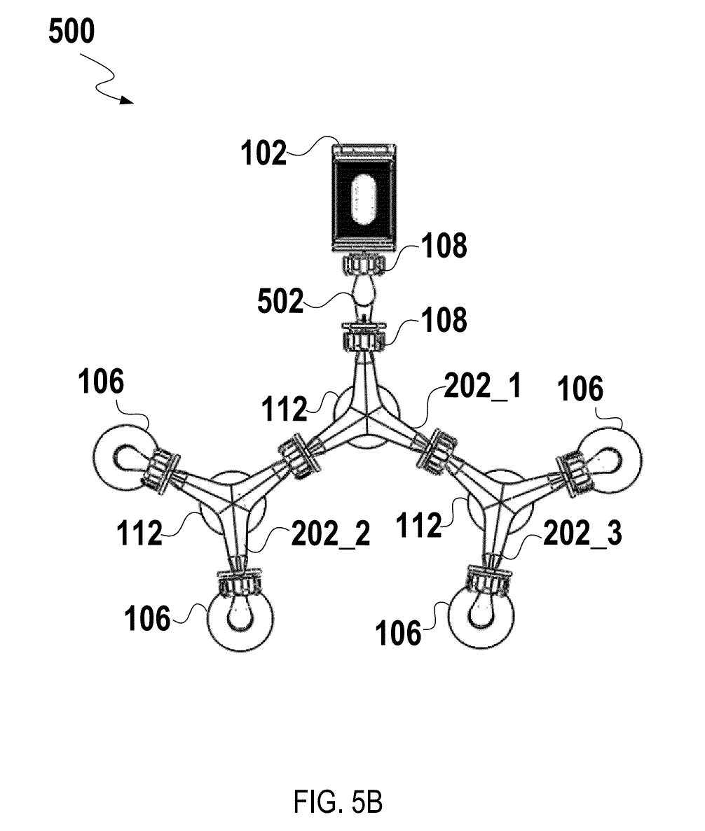

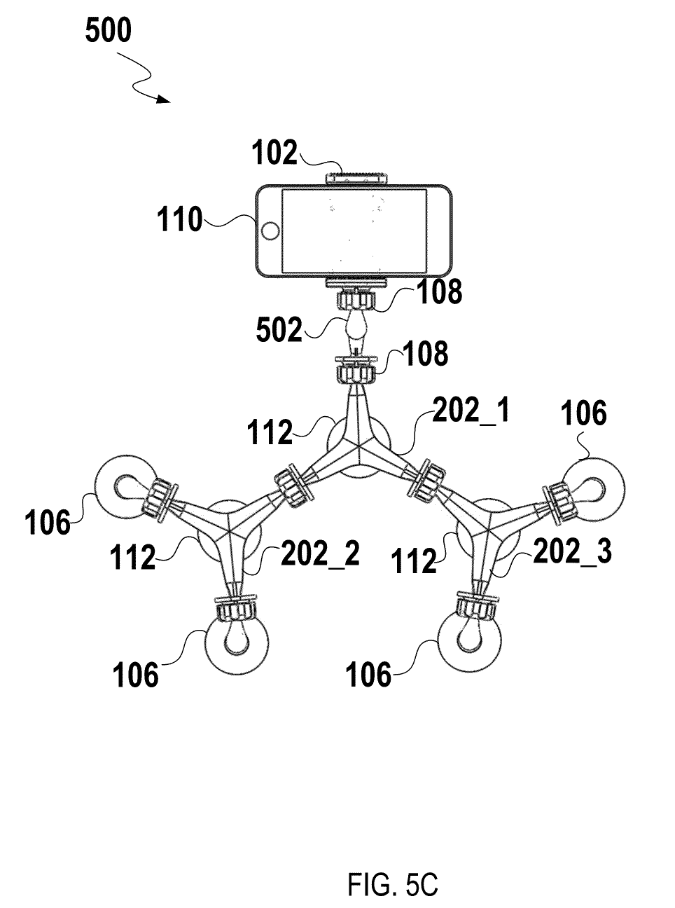

FIG. 5A-5C illustrates a mounting system 500 which can mount a mobile device and can attach to a vehicle, in accordance with an embodiment of present disclosure. Elements labeled as the same in FIGS. 2A-4C have similar functions. FIG. 5A illustrates a lateral view of mounting system 500. As shown in FIG. 5A, housing component 102 is attached to a surface of the vehicle through a mixed mode combination of attachment devices and supporting brackets. More specifically, based on mounting system 300 in FIG. 3A, mounting system 500 further includes a supporting bracket 502. Supporting bracket 502 includes a straight body and two end portions. As shown in FIG. 5A, an end portion of supporting bracket 502 bends and forms an angle of 90 degrees with the body upwardly. While the other end portion bends and forms an angle of 90 degrees with the body downwardly. In addition, the downward end portion of supporting bracket 502 may be a flat end and is connected to the lower mounting component through a connecting portion 108. The upward end portion of supporting bracket 502 may be a ball-end and is connected to housing component 102 through another connecting portion 108. The lower mounting component includes multiple supporting brackets, multiple attachment devices and multiple connecting portions. FIG. 5B illustrates a front view of mounting system 500. FIG. 5C illustrates a front view of mounting system 500 with a mobile device (e.g., a mobile phone 110) attached. Advantageously, mounting system 500 can be adapted to fit more complex surfaces, even a surface with steps or curves. In addition, although, mounting system 500 only shows a one-branch supporting bracket 402 connects to three three-branch supporting bracket 202_1, 202_2 and 202_3, the mounting system of the present disclosure also intends to cover embodiments which include more supporting brackets connected with each other to further improve the flexibility and stability of the mounting system. Furthermore, it can be understand that the three-branch supporting brackets can be replaced by supporting brackets with any other number of branches.

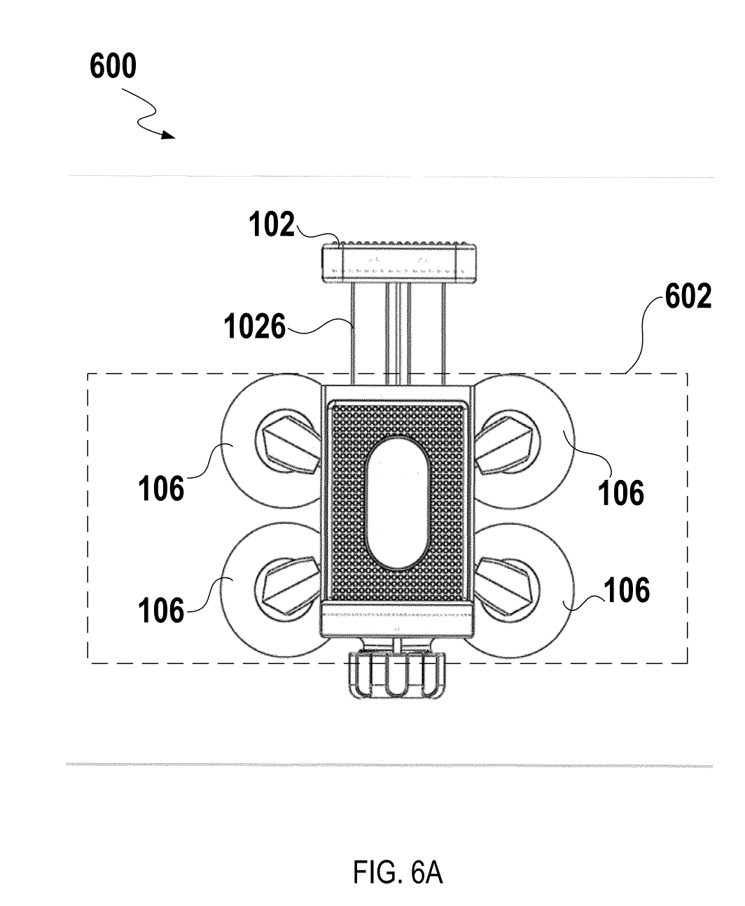

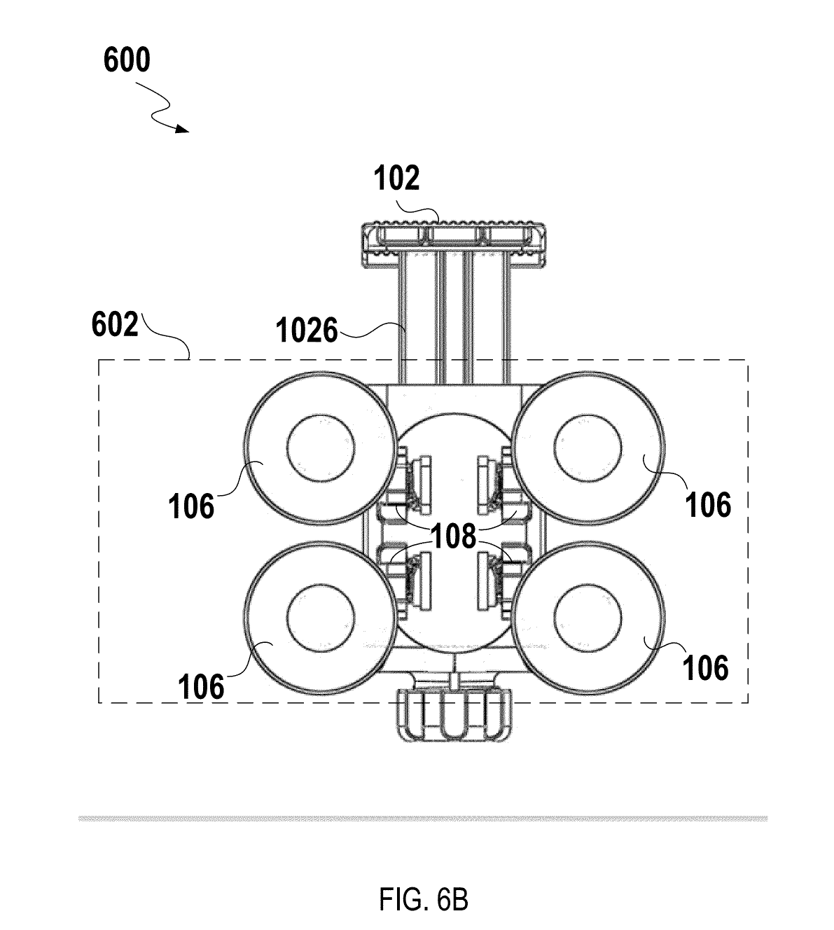

FIG. 6A-6B illustrates a mounting system 600 which can mount a mobile device and can attach to a vehicle, in accordance with an embodiment of the present disclosure. Elements labeled as the same in FIGS. 1A-1E have similar functions. FIG. 6A illustrates a front view of mounting system 600. FIG. 6B illustrates a back view of mounting system 600. As shown in FIG. 6B, mounting system 600 includes an upper mounting component 602. Upper mounting component 602 includes four attachment devices 106 and four connecting portions 108. More specifically, each of the four attachment devices 106 is attached to the back of housing component 102 through connecting portions 108 respectively. As described above, each of the attachment devices 106 has a ball-end which can rotate in sockets of connecting portions 108 and has 360-degree adjustment. Alternatively, in other embodiments, the position of the four attachment devices 106 can be adjusted according to practical needs. In addition, it can be understood that the upper mounting component can include other number of attachment devices with different shapes and types through other securing mechanism.

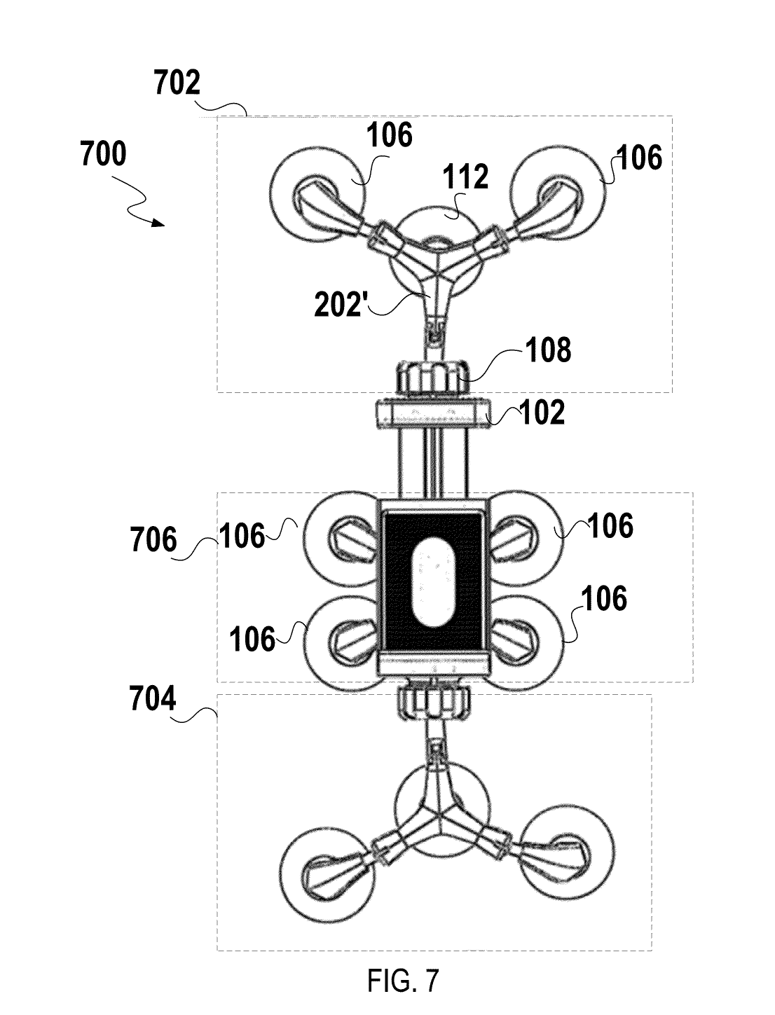

FIG. 7 illustrates a front view of a mounting system 700, in accordance with another embodiment of the present teaching. Elements labeled as the same in FIG. 2A-2G have similar functions. Mounting system 700 includes a housing component 102 and securing component. The securing component is coupled to housing component 102 and is configured to secure mounting system 700 to a surface. The securing component includes a first mounting component 702 and a second mounting component 704. First mounting component 702 is disposed at a bottom of housing component 102. Second mounting component 704 is placed at a top of housing component 102. As shown in FIG. 7, first mounting component 702 and second mounting component 704 can be the same structure as lower mounting component 204 described in FIG. 2G which comprises of a supporting bracket 202′, two attachment devices 106, a third attachment device 112 and three connecting portions 108. Alternatively, first mounting component 702 and second mounting component 704 can be any other adaption of lower mounting component 204. Advantageously, with these two mounting components, both the two ends of housing component 102 are secured to the surface of the vehicle. The stability of mounting system 700 is enhanced. In addition, the securing component of mounting system 700 may further include a third mounting component 706 placed at the back of housing component 102 and configured to secure housing component 102 to the surface from a back side of housing component 102. Third mounting component 706 can be similar to upper mounting component 602 as shown in FIG. 6. Alternatively, third mounting component 706 can be any other adaption of the upper mounting component, (e.g., the upper mounting component as shown in FIG. 1A-1F).

In additional alternative embodiments, the mounting system of the present disclosure can be mounted to any vehicle other than a scooter. For example, the mounting system can be attached to a motorcycle, a bicycle or a car.

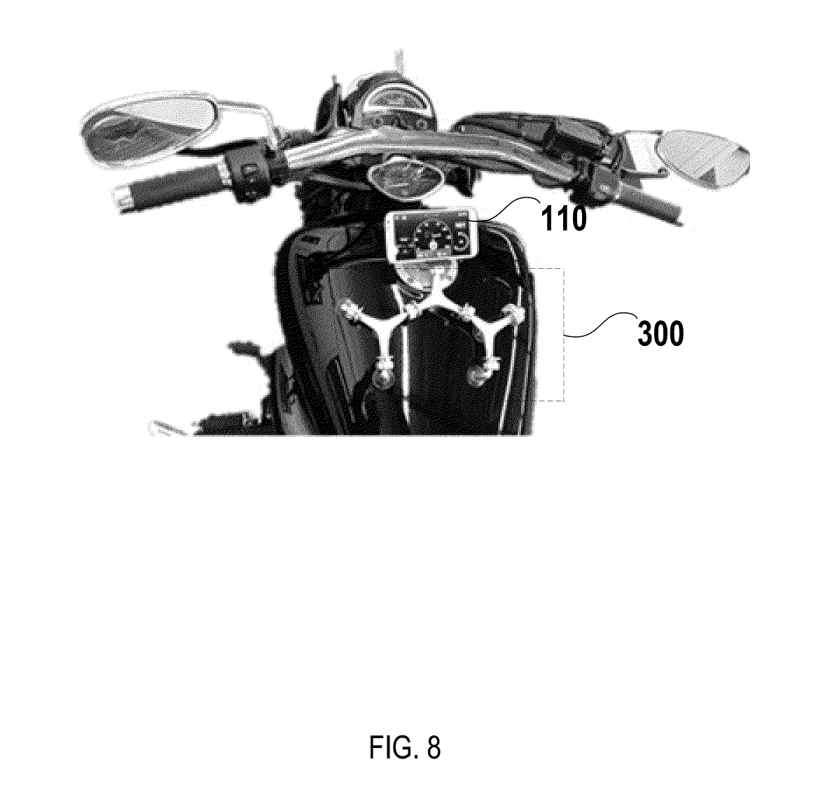

More specifically, FIG. 8 illustrates a front view of mounting system 300 attached to a motorcycle with a mobile device mounted, in accordance with an embodiment of the present disclosure. As shown in FIG. 8, mounting system 300 is mounted on the front of the motorcycle. More specifically, mounting system 300 can be mounted on a surface near the gasoline tank of the motorcycle. The mobile device (e.g., the mobile phone 110) can be used as a dashboard of the motorcycle while driving.

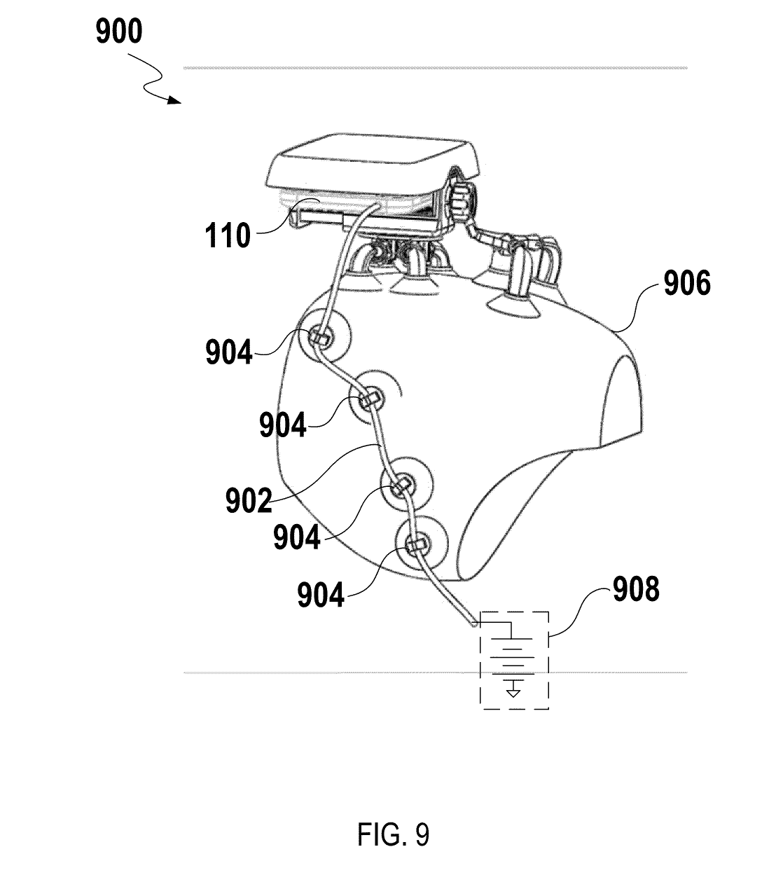

In addition, an extra electrical wire may be included in mounting system of the present teaching. FIG. 9 illustrates a mounting system 900 mounted on a surface of a motorcycle which includes an electric wire 902, in accordance with the present disclosure. The electrical wire is connected from battery 908 of the motorcycle to mobile device 110 and is configured to provide electric power to mobile device 110. As shown in FIG. 9, except electric wire 902, mounting system 900 further includes multiple cable holders 904. Each of the multiple cable holders 904 is secured by an attachment device attached (e.g., a suction cup) at the back side. The extra electric wire 902 can be fixed by cable holders 904 along gasoline tank 906 of the motorcycle. Advantageously, with the electrical wire, a user can charge the mobile phone while driving the gasoline motorcycle.

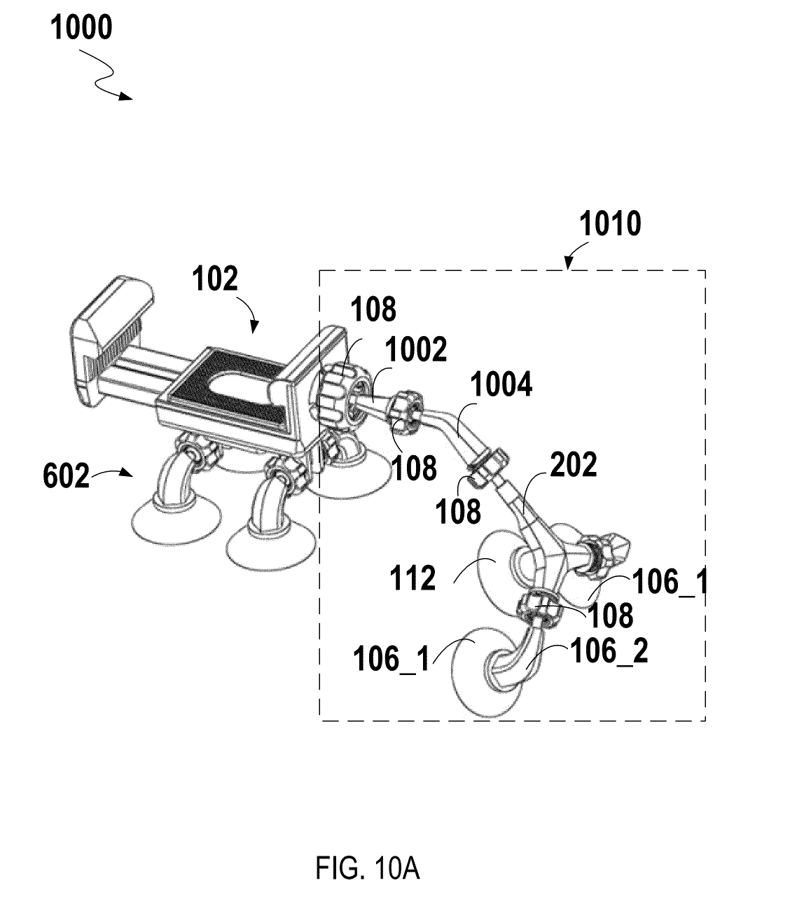

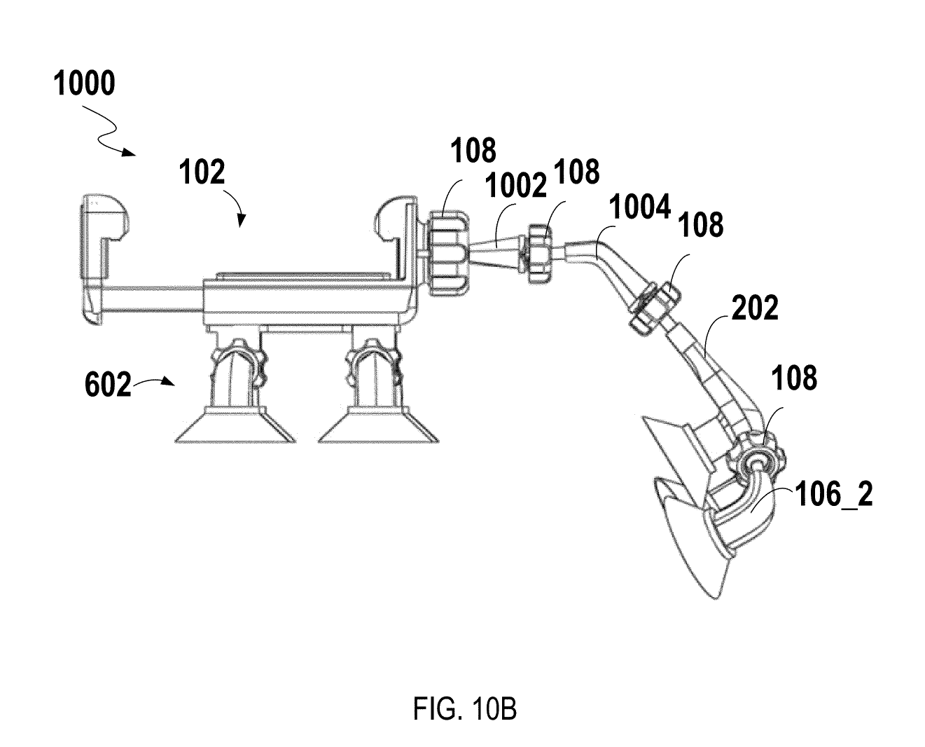

FIG. 10A illustrates a mounting system 1000, in accordance with another embodiment of the present disclosure. FIG. 10B illustrates a lateral view of mounting system 1000. Based on mounting system 600 in FIG. 6A, mounting system 1000 further includes a lower mounting component 1010. As shown in FIG. 10A, lower mounting component 1010 includes four kinds of supporting brackets: a first supporting bracket 1002, a second supporting bracket 1004, a third supporting bracket 202 as described in FIG. 2A, and a fourth supporting bracket 106_2 as described in FIG. 1A. First supporting bracket 1002 has a straight branch and a ball-end which is connected to housing component 102 through a connecting portion 108. Second supporting bracket 1004 has a bent branch and a ball-end which is connected to first supporting bracket 1002 through another connecting portion 108. As shown in FIG. 10A, second supporting bracket 1004 is bent with an angle of 45 degrees. In other embodiment, second supporting bracket may be bent with other angles. Third supporting bracket 202 is connected to second supporting bracket 1004 through a connecting portion 108 as well. Third supporting bracket 202 has three branches as described above. Each of three branches is connected with a fourth supporting bracket 106_2. Fourth supporting bracket 106_2 also has a ball-end and connects to third supporting bracket 202 through a connecting portion 108. In addition, fourth supporting bracket 106_2 has a bent branch with an angle of 90 degrees as described in FIG. 1A. It can be understood that the lower mounting components of mounting system of the present disclosure can include more supporting brackets with different kinds connected in similar ways.

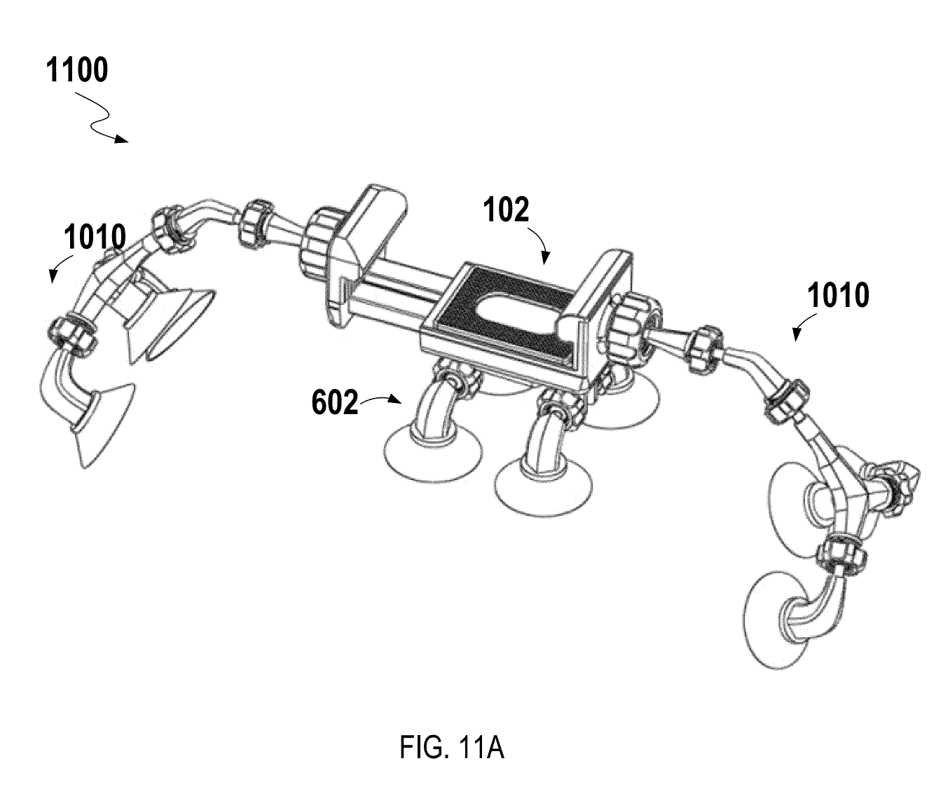

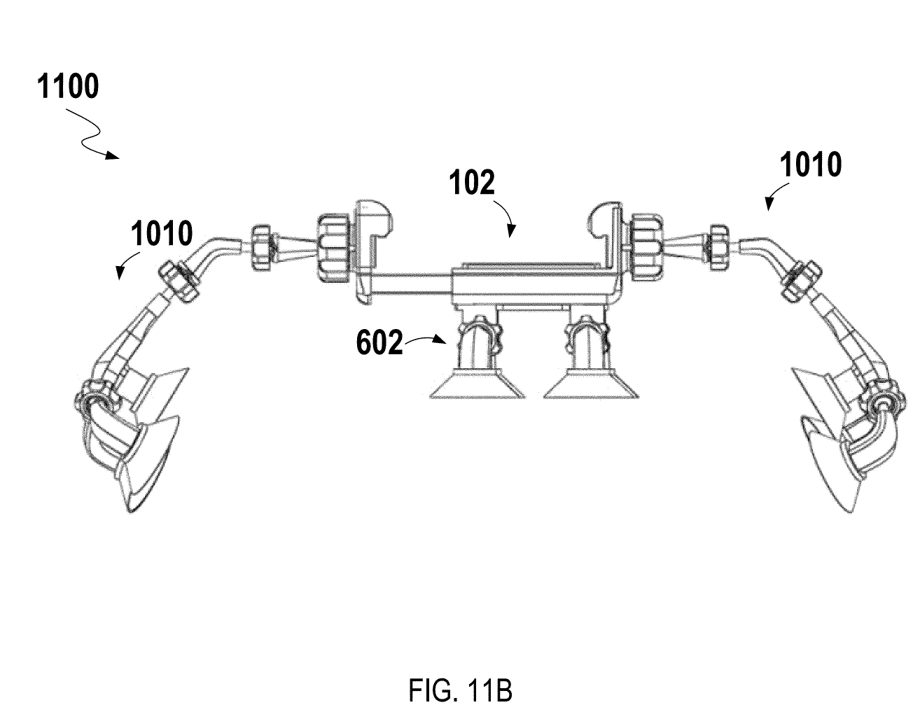

FIG. 11A illustrates a mounting system 1100, in accordance with another embodiment of the present disclosure. FIG. 11B illustrates a lateral view of mounting system 1100, As shown in FIG. 11A, similar with structure of mounting system 700 in FIG. 7, mounting system 1100 includes two lower mounting components 1010. One is secured at top side of housing component 102. The other is secured at bottom side of housing component 102. Advantageously, the attaching strength of mounting system 1100 is further enhanced.

The above figures are used for illustrative purpose only, and are not intended to limit the present disclosure. Other adaption of other mounting structures can also be included within the spirit and scope of the present disclosure.

The embodiments of the present disclosure provide mounting systems for mounting a mobile device. The mounting system can be attached to surface of vehicles. The mounting system includes multiple attachment devices which can have 360-degree adjustment such that the attaching direction can be adjusted in a large range. Taking mounting system 200′ in the FIGS. 2F and 2G as an example. Benefited from the ball-end attachment device and the foldable branch of the supporting bracket, the attachment devices 112 and 106 of the lower mounting component can be attached to a first surface of a vehicle (e.g., a surface facing a forward direction of a driver) and the attachment device 104 of the upper mounting component can be attached to a second surface of the vehicle (.e.g., a dashboard of the electric bike which faces toward the driver), while an angle between the first surface and the second surface can be any degree. Therefore, both the strength and the flexibility of the mounting system can be enhanced. The mounting system can be easily attached to a surface of the vehicle in a variety of positions and angles according to users' convenience and preference. In addition, depending on the particular attachment devices used in the particular embodiment, the mounting system can be easily mounted and dismounted without extra instruments.

While the foregoing description and drawings represent embodiments of the present disclosure, it will be understood that various additions, modifications and substitutions may be made therein without departing from the spirit and scope of the principles of the present disclosure as defined in the accompanying claims. One skilled in the art will appreciate that the disclosure may be used with many modifications of form, structure, arrangement, proportions, materials, elements, and components and otherwise, used in the practice of the disclosure, which are particularly adapted to specific environments and operative requirements without departing from the principles of the present disclosure. The presently disclosed embodiments are therefore to be considered in all respects as illustrative and not restrictive, the scope of the disclosure being indicated by the appended claims and their legal equivalents, and not limited to the foregoing description.

We claim:

1. A mounting system, comprising:
a housing component configured to secure a device; and
a securing component coupled to the housing component and configured to secure the mounting system to a surface,
wherein the securing component comprises a lower mounting component configured to secure the housing component to the surface from a bottom side of the housing component, wherein the lower mounting component comprises:
a first connecting portion configured to connect the lower mounting component to a bottom of the housing component; and
a first attachment device configured to attach to the surface.

2. The mounting system of claim 1, wherein the first connecting portion is further configured to connect the first attachment device to the housing component.

3. The mounting system of claim 1, wherein the first attachment device has a ball-end.

4. The mounting system of claim 3, wherein the first connecting portion comprises a ball joint socket which mates with the ball-end of the first attachment device.

5. The mounting system of claim 1, wherein the securing component further comprises an upper mounting component placed at a back portion of the housing component and configured to secure the housing component to the surface from back side of the housing component.

6. The mounting system of claim 5, wherein the upper mounting component comprises a plurality of attachment devices configured to attach to the surface, and wherein positions of the plurality of attachment devices are adjustable.

7. The mounting system of claim 1, wherein the mounting system further comprises an electrical wire which is configured to provide electric power to the device.

8. The mounting system of claim 1, wherein the lower mounting component comprises a first supporting bracket which has one branch and wherein both two ends of the branch are ball-ends, wherein the first connecting portion comprises a ball joint socket which mates with the ball-end of the first supporting bracket, and wherein a second end of the branch is configured to connect with the first attachment device.

9. The mounting system of claim 1, wherein the lower mounting component comprises a first supporting bracket which has three branches joined at a first vertex and wherein an angle between any two neighboring branches is 120 degrees.

10. The mounting system of claim 9, wherein the lower mounting component further comprises a second attachment device located at the first vertex, wherein the second attachment device is configured to attach to a surface.

11. The mounting system of claim 9, wherein a first branch of the first supporting bracket is configured to connect to the housing component through the first connecting portion, and a second branch of the first supporting bracket is configured to connect to the first attachment device.

12. The mounting system of claim 11, wherein the first branch of the first supporting bracket is foldable.

13. The mounting system of claim 11, wherein the first branch of the first supporting bracket has a ball-end and the first connecting portion comprises a ball-joint socket which mates with the ball-end branch of the first supporting bracket.

14. The mounting system of claim 9, wherein the lower mounting component comprises:
a second supporting bracket which has three branches joined at a second vertex; and
a second connecting portion configured to connect the first supporting bracket with the second supporting bracket.

15. The mounting system of claim 14, wherein a first branch of the second supporting bracket has a ball-end and the second connecting portion comprises a ball joint socket which mates with the ball-end of the first branch.

16. The mounting system of claim 14, wherein a second branch of the second supporting bracket is connected with the first attachment device through a third connecting portion, wherein the first attachment device has a ball-end and wherein the third connecting portion comprises a ball joint socket which mates with the ball-end of the first attachment device.

17. The mounting system of claim 1, wherein the housing component comprises a waterproof cover, and wherein the housing component is waterproof when the cover is in closed position.

18. The mounting system of claim 1, wherein the mounting system comprises a first supporting bracket which has a bent branch and a ball-end.

19. The mounting system of claim 1, wherein the attachment device comprises a suction cup, a permanent magnet, a magnetic latch, an adhesive, a fastener, or any combination thereof.

20. A mounting system, comprising:
a housing component configured to secure a device; and
a securing component coupled to the housing component and configured to secure the mounting system to a surface, wherein the securing component comprises:
a first mounting component which is placed at a bottom of the housing component and is configured to secure the housing component to the surface from bottom side; and
a second mounting component which is placed at a top of the housing component and is configured to secure the housing component to the surface from top side.
